(19) United States
(12) Patent Application Publication
(10) Pub. No.: US 2002/0061663 A1
(43) Pub. Date: May 23, 2002

(54) Power supply output cable of metal plates soldered to connection interfaces with embedded capacitor array to provide low inductance rapid startup current

(75) Inventors: Bruce C.H. Cheng, Taipei (TW); Timothy Chen-Yu Yu, Taipei (TW); Kelly Jui-Yuan Shyu, Taipei (TW); Szu-Lu Huang, Taipei (TW)

Correspondence Address: Bo-In Lin, 13445 Mandoli Drive, Los Altos Hills, CA, 94022, US

(73) Assignee: Delta Electronics, Inc.

(21) Appl. No.: 10/045,974

(22) Filed: Jan. 15, 2002

Related U.S. Application Data
(63) Continuation-in-part of application No. 09/375,470, filed on Aug. 15, 1999.
(60) Provisional application No. 60/096,674, filed on Aug. 15, 1998.

(51) Int. Cl. H05K 1/00; H01R 12/00

(52) U.S. Cl. 439/60

(57) ABSTRACT

The present invention discloses power supply cable for providing DC power from a power supply to a microprocessor of a personal computer. The output cable includes a plate-cable includes a first and a second metal plates insulated with an insulation layer between the first and second metal plates. The output cable further includes a plurality of capacitors disposed on the plate cable. Each of the capacitors has a first and second electrical terminals and each of the first and second electrical terminals connected to one of the first and second metal layers provided for storing electrical charges therein for transmitting through the metal layers for supplying power to the microprocessor. In a preferred embodiment, the plurality of capacitors disposed on the first metal plate with the first electrical terminal for each of the capacitors connected to the first metal plate. The plate-cable further includes a plurality of via-connectors penetrating the insulation layer for connecting the second electrical terminal for each of the capacitors to the second metal plate. In another preferred embodiment, the plate-cable further includes multiple insulated plate-segments each of the plate-segment is provided for supplying power of a different voltage to the microprocessor. In another preferred embodiment, the output cable further includes a microprocessor connector socket soldering to an output end the plate-cable.

This Application is a Continuation-in-Part Application of a previously filed Provisional Application 60/096,674 filed on Aug, 15, 1998 and a Formal application Ser. No. 09/375,470 filed on Aug. 14, 1999, by the same Inventors of this Patent Application.

### BACKGROUND OF THE INVENTION

1. Field of the Invention

This invention relates generally to the structure and design method for electrical connectors. More particularly, this invention relates to a new configuration and design method for manufacturing and assembling a power-supply electrical output cable with two face-to-face conductive plates insulated with an thin insulation film provided with capacitor array for minimizing time delay in starting a computer process with sufficient initial current.

2. Description of the Prior Art

A technical difficulty is now faced by the power supply industry as the computer and many different kinds of hand held electronic devices are operated with a lower direct-current (DC) voltage, i.e., DC voltage or 3.3 volts or lower, and higher loading current. One major requirement for providing a DC power supply to the computer or hand held devices is to minimize the voltage drop and also to quickly ramp up the current to expeditiously start up the device. Conventional power supply connection implemented with a power supply cable has many inherent limitations. First limitation is time of current transmission causes delay in device startup due to the requirement that large amount of electrons have to pass through the entire length of the power supply cable and that causes delays in device startup. Furthermore, the length of an output cable of a power supply for supplying power to an electronic device such as a personal computer introduces additional resistance and leads to undesirable increase in voltage drops. Additionally, the voltage drops may be caused by connector inductance induced by variations of the dynamic loading current. FIG. 1A is a circuit diagram showing the connector between a voltage power source 10 and a microprocessor 20. A conventional connector typically includes two conductive lines to form a closed electric current loop. Between these conductive lines, a parasitic capacitor 30 and inductor 40 are generated. During a sleeping mode of the microprocessor, there is a very small steady DC current conducted from the power supply system 10 to the microprocessor 20. At an instant of microprocessor wake-up, a rate of instantaneous current variation on the conductive lines is approximately two hundred amperes per microsecond, i.e., 2×10⁸ A/μs. With an inductance of two nano-Henries (2.0 nH), an instantaneous voltage drop due to the connector inductance is:

L(dI/dt)=(1×10⁻⁹)(2×10⁸)=0.2 volts (1)

Where (dI/dt) is the rate of current variation, L is the inductance. According to this equation, a voltage drop of 0.2 volts is generated due to a high current ramp-up rate. As a result of the connector inductance, the microprocessor 20 experiences a significant voltage drop as that shown in FIG. 1B. At the time of the wake-up of the microprocessor 20, there is an instantaneous increase in current and in response, a sharp voltage drop is experienced by the microprocessor 20. Due to this sharp voltage drop, there is a serious concern that if the voltage is dropped below the minimum operation voltage required by the microprocessor for a period of time, some information might be lost during data processing. Even the voltage drop does not cause a data loss, it may cause a delay in waking up the microprocessor. Performance of the microprocessor is degraded due to the inductance induced voltage drop.

In a first co-pending patent application filed by a same inventor of this invention, a connector configured as a near-zero inductance connector is disclosed to resolve these difficulties by providing a very thin connector comprising overlapping conductive layers as input and output terminals. Also, in a second co-pending patent application a new configuration with a simplified and cost effective method to assemble the near-zero inductance connector for long term reliable operation method is disclosed. In these applications, a near-zero inductance connector with improved structural reliability is disclosed. However, these inventions are still not provided to resolve the difficulties that rapid startup currents are often difficult to achieve. The difficulties are not resolved due to facts that the startup currents are transmitted over the length of the output cable of these power supply systems even with near zero inductance and reliable structural integrity.

Therefore, an improved cable and connector for connecting the power supply system to the microprocessor and to shorten the distance between the current source to the processor are required to resolve these difficulties. Specifically, a new configuration and design method are required for constructing a cable and the connector to reduce the distance of current transmission and to reduce the resistance and inductance to a very low level. A cable provided with electric charge storage means such as capacitor would be necessary to shorten the startup current-ramp up time. Also, a connector provided with a near zero inductance would reduce the voltage drop caused by connector inductance due to the variations of dynamic current and that would also lower the heat produced.

### SUMMARY OF THE PRESENT INVENTION

It is therefore an object of the present invention to provide a novel configuration and method of design and manufacturing of a power supply output cable for providing power to a microprocessor. The novel and improved output cable is to significantly shorten the distance of current transmission and to reduce the connector inductance during the time when there is a great rate of current variations such that the aforementioned limitations and difficulties encountered in the prior art can be overcome.

The present invention therefore provides a novel configuration and method of design and manufacturing of an output cable for providing power to a microprocessor. The novel and improved output cable can significantly reduce the time required for ramping up the startup currents for operating an electronic device by configuring the output cable as plates and disposing capacitors on the output cable as capacitor array. The output plate cable further reduces the connector inductance during the time when there is a great rate of current variations such that the limitations and difficulties encountered in the prior art can be overcome. Specifically, the present invention provides a cable plate with capacitors attached to the plate for storing up electrical charges to rapidly providing current during a startup operation. The plate cable further is soldered to the electrical terminals connecting to the central process unit (CPU) to provide more reliable connection with lower resistance thus generating less voltage drops. The plate cable further has a current conduction configuration with the current generated magnetic field canceled out.

Specifically, it is an object of the present invention to provide a configuration and method of design and manufacturing of a power supply output cable as a two insulated plates provided with capacitor array. The novel plate cable is able to provide large startup currents to a microprocessor rapidly such that initial startup delay can be minimized. The output cable further has a current conduction configuration with the current generated magnetic field canceled out. By substantially canceling out the current generated-magnetic field, the inductance is reduced to a very low level. The voltage drop and heat production caused by connector inductance can be significantly reduced.

Another object of the present invention is to provide a configuration and method of design and manufacturing of a power supply output cable by soldering the plate output cable to the power supply and to the connecting terminals to the CPU. The new and improved output cable thus provides more reliable connections with lower transmission resistance.

Another object of the present invention is to provide an improved configuration and method of design and manufacturing of a power supply cable by employing plate cable comprising parallel conductive layers for conducting DC currents insulated by a heat conductive insulation layer. Furthermore, the connector is assembled and protected by a heat conductive insulation layer such that heat generated through current conducting in the connector can be more effectively removed.

Briefly, in a preferred embodiment, the present invention discloses power supply cable for providing DC power from a power supply to a microprocessor of a personal computer. The output cable includes a plate-cable includes a first and a second metal plates insulated with an insulation layer between the first and second metal plates. The output cable further includes a plurality of capacitors disposed on the plate cable. Each of the capacitors has a first and second electrical terminals and each of the first and second electrical terminals connected to one of the first and second metal layers provided for storing electrical charges therein for transmitting through the metal layers for supplying power to the microprocessor. In a preferred embodiment, the plurality of capacitors disposed on the first metal plate with the first electrical terminal for each of the capacitors connected to the first metal plate. The plate-cable further includes a plurality of via-connectors penetrating the insulation layer for connecting the second electrical terminal for each of the capacitors to the second metal plate. In another preferred embodiment, the plate-cable further includes multiple insulated plate-segments each of the plate-segment is provided for supplying power of a different voltage to the microprocessor. In another preferred embodiment, the output cable further includes a microprocessor connector socket soldering to an output end the plate-cable.

These and other objects and advantages of the present invention will no doubt become obvious to those of ordinary skill in the art after having read the following detailed description of the preferred embodiment which is illustrated in the various drawing figures.

### BRIEF DESCRIPTION OF THE DRAWINGS

FIG. 1A is a circuit diagram showing the connection between a power supply to a microprocessor having a parasitic capacitor and a parasitic inductor;

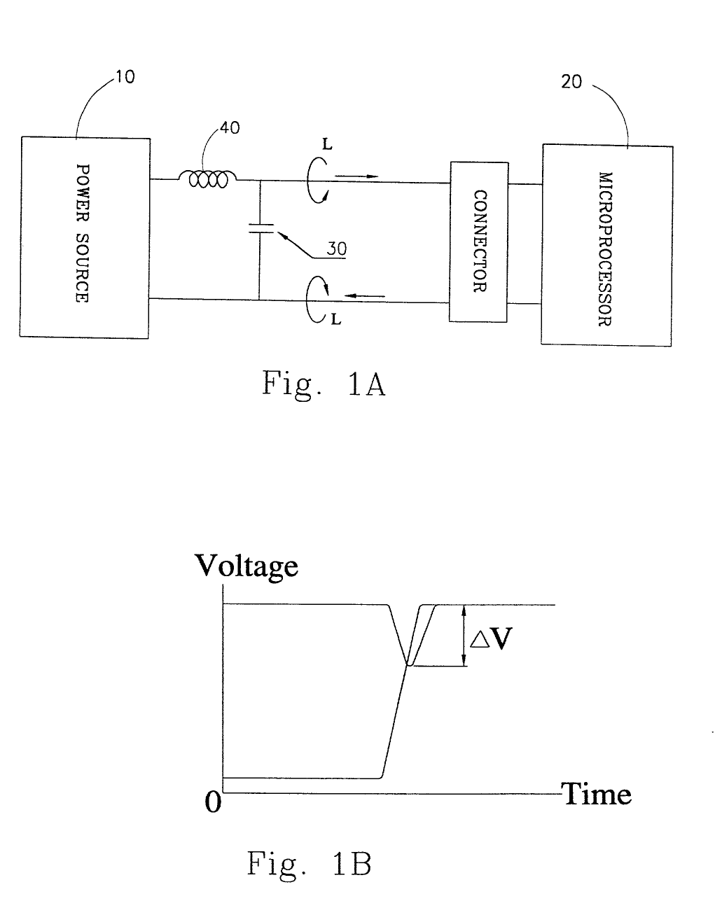

FIG. 1B is a diagram showing the variations of current and voltage of the connector at the time when the microprocessor wakes up from a sleeping mode;

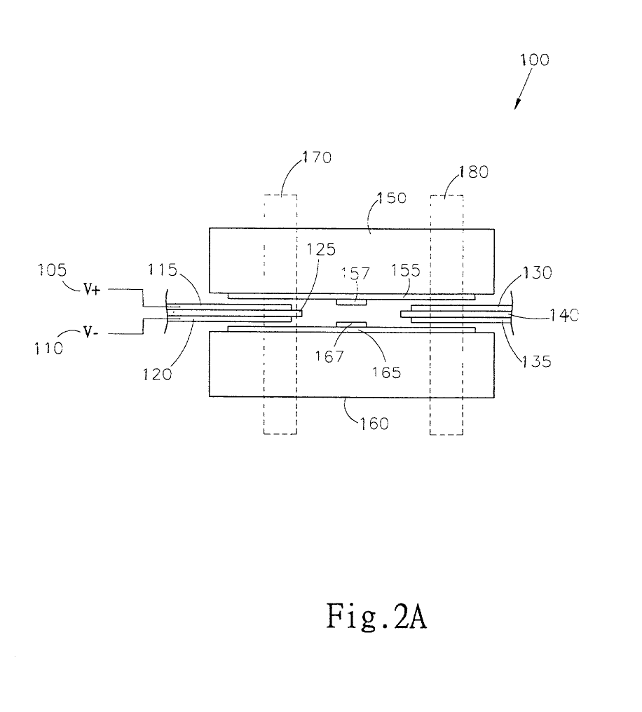

FIGS. 2A and 2B are respectively cross sectional view and perspective view of a connector of this invention where the current generated magnetic fluxes are mutually canceled out;

FIG. 3 is a functional block diagram showing a near-zero inductance connector of this invention connected between a power supply and a computer for providing a DC voltage; and

FIG. 4 is a cross sectional view for showing special tapered insulation and protection covers of this invention;

FIG. 5A is a perspective view and FIGS. 5B and 5C are cross sectional views for illustrating a horizontal movement of a locking cartridge to lock the near-zero inductance connector to a print circuit board; and

FIGS. 6A and 6B are a top view and a side cross sectional view of a power supply output cable of this invention and FIG. 6C is an exploded side cross section view of the plate cable of FIG. 6A.

### DETAILED DESCRIPTION OF THE PREFERRED EMBODIMENT

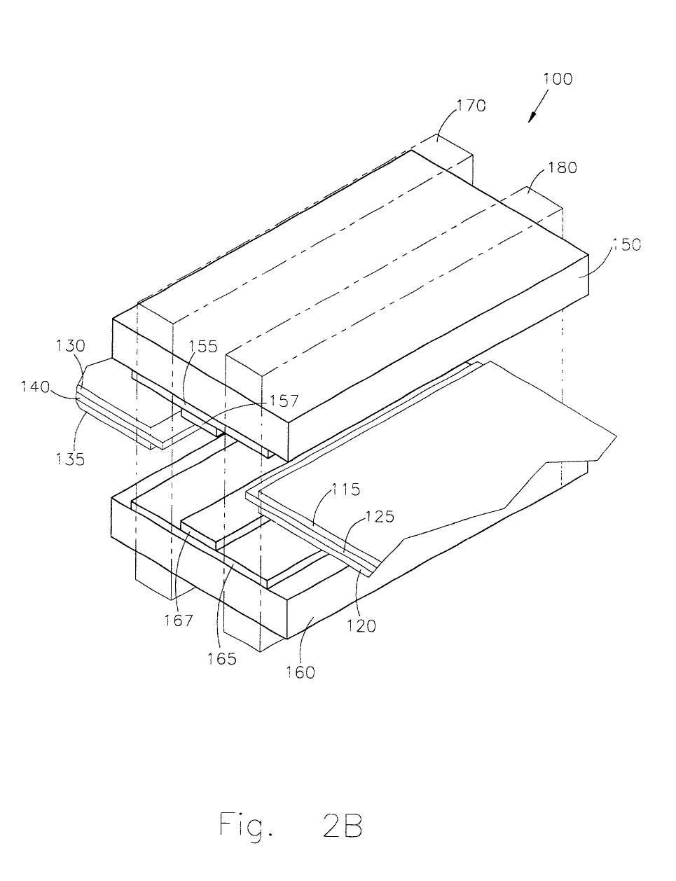

FIGS. 2A and 2B are respectively a cross sectional view and a perspective view of a novel electrical connector with a near zero inductance. The electrical connector 100 includes an input end for connecting to a positive voltage electrode 105 and a negative electrode 110. The positive electrode 105 connected to an input high voltage thin conductive layer 115 and the negative electrode 110 connected to an input low voltage thin conductive layer 120. The input high-voltage thin conductive layer 115 is insulated from the input low voltage thin conductive layer 120 by an input insulation layer 125. The electrical connector 100 further includes an output end. Similarly, the output end includes an output high voltage thin conductive layer 130 and an output low voltage thin conductive layer 135 insulated by an output insulation layer 140. These conductive layers insulated by an insulation layer are clipped between a top insulation layer 150 and a bottom insulation layer 160. The top insulation layer 160 and bottom insulation layer 160 each has an inner conductive layer 155 and 165 respectively. The inner conductive layer 155 is in electrical contact with input the high-voltage thin conductive layer 115 and the output high voltage thin conductive layer 130. The inner conductive layer 165 is in electrical contact with input the low-voltage thin conductive layer 120 and the output low voltage thin conductive layer 135. The top and bottom insulation layer 150 and 160 are composed of electrical insulation material with high coefficient of heat conductivity. Preferably, such layers may be insulation layers composed of Kapton produced by DuPont. The top and bottom inner conductive layers 155 and 165 are further insulated from each other by an inner insulation layer 157 and 167 respectively attached at the inner surface to the inner conductive layer 155 and 165 facing each other. It is therefore assured that inner conductive layer 155 will not shorted to the inner conductive layer 165. Two clips 170 and 180 are then applied to clip the top insulation layer 150 and the bottom insulation layer 160 together to keep these conductive and insulation layers securely in fixed positions.

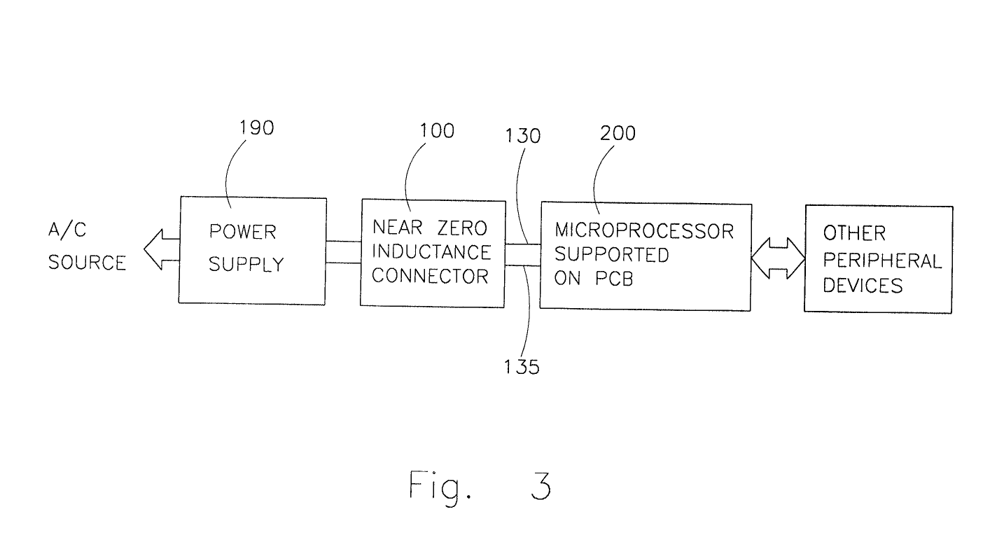

The electric connector 100 provides several advantages over the conventional connectors. First advantage of this connector 100 is a very low inductance of this connector. The near-zero inductance is the result of the special structure. Because of the special structure, the high voltage conductive layers 115 and 130 are immediately adjacent and parallel to the low voltage conductive layers 120 and 135. Therefore, the magnetic field produced by variations of current transmitting through the high voltage layers, layers 115 and 130 are almost totally canceled out by the magnetic field produced by corresponding current variations in the low voltage conductive layers 120 and 135. FIG. 3 illustrates the cancellation of the magnetic fluxes produced in the high voltage and the low voltage layers. As shown in the diagram, the high voltage conductive layers are transmitting current in one direction, e.g., to the right, while the low voltage conductive layers are transmitting current in an opposite direction, e.g., to the left. Because the high voltage conductive layers and the low voltage conductive layers are immediately adjacent and parallel to each other, two set of magnetic fluxes are generated by the high-voltage and low-voltage conductive layers. These two sets of magnetic fluxes are substantially equal in magnitude and pointing to opposite in directions. These two sets of magnetic fluxes produced by conducting currents in these high and low voltage conductive layers thus cancel out each other.

FIG. 3 is a functional block diagram showing the connector 100 with a near-zero inductance of this invention, connected between a power supply 190 and a microprocessor 200. The microprocessor may a high-speed data processing system supported on a printed circuit board (the PCB is well known and not specifically shown). The output high voltage conductive layer 130 and the output low-voltage conductive layer 135 are connected respectively to a high voltage terminal and a ground terminal on the printed circuit board (PCB) of the microprocessor.

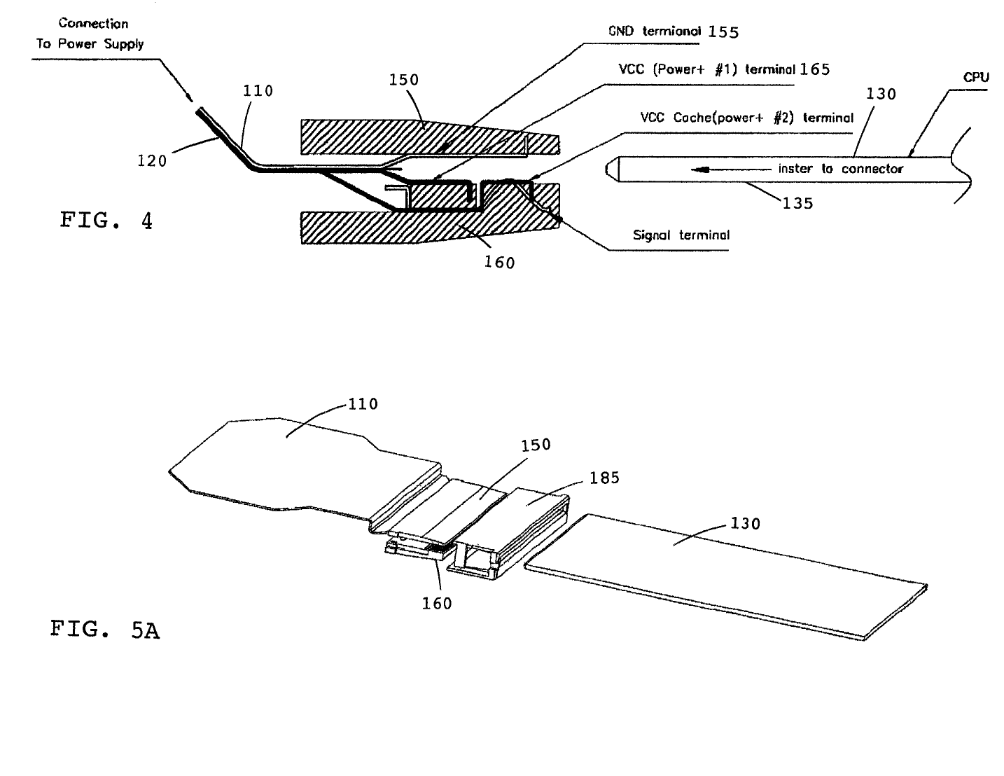

FIG. 4 is a cross sectional view of actual implementation of the near zero inductance connector 100. Specifically, the top insulation and protection cover 150 and the bottom insulation and protection cover are formed with a special tapered outer surface. The connector 100 thus has a special tapered profile having a gradually reduced cross sectional profile height along the horizontal direction toward the opening for receiving the printed circuit board 130.

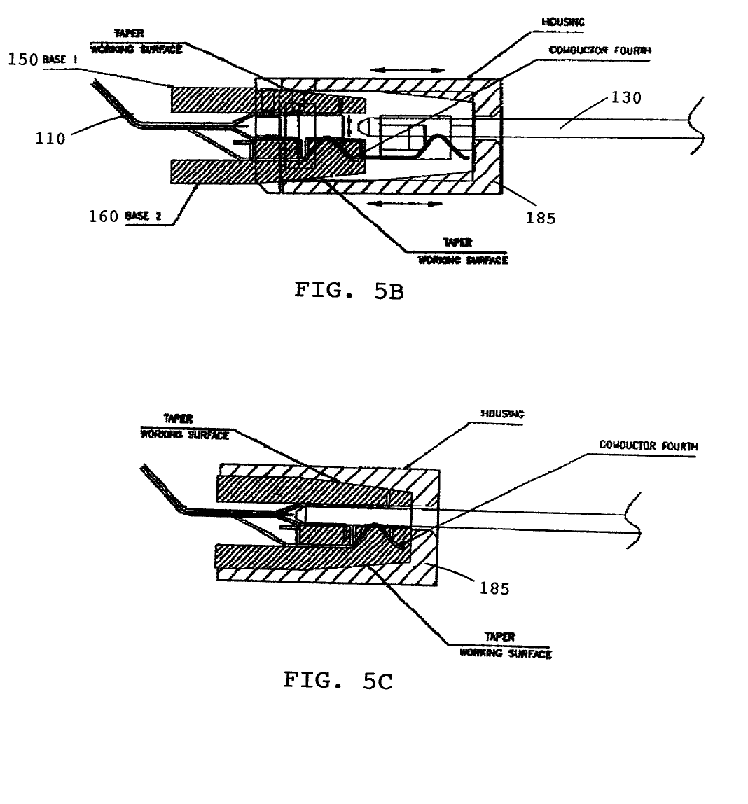

Referring to FIGS. 5A to 5C for a particular locking cartridge 185 of this invention to conveniently and securely lock several terminal layers of the near-zero inductance connector 100 such that the connector can sustain long term reliable operation. Instead of employing the clips 170 and 180 as shown in FIG. 2A, as shown in FIGS. 5A to 5C, the locking cartridge has an opening to receive the tapered end with reduced profile height into the cartridge 185. By pushing the locking cartridge 185 toward the power supply side, the gradually increased profile height of the outer insulation and protection covers 150 and 160 converts a horizontal pushing force to a vertical pressing force. The vertical pressing force is asserted against different input and output terminal layers and the insulation layers of the near-zero inductance connector 100. A simple horizontal pushing movement of the locking cartridge thus securely locks and assembles the near-zero inductance connector into a reliable operational unit without requiring extra mechanical or soldering or bonding processes or components.

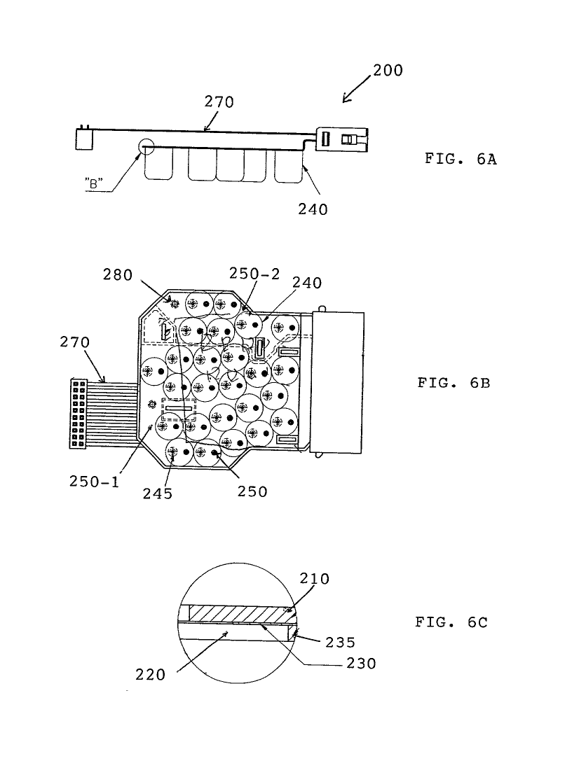

FIGS. 6A and 6B are a top view and a side cross sectional view respectively of a power-supply output cable 200 of this invention. The power-supply output cable is formed as a plate 205 that includes a top plate 210 and a bottom plate 220 insulated with an thin insulation film 230 (FIG. 6C). The top and bottom plates are preferably copper plates wherein the top plate and the bottom plate are conducting currents transmitting in opposite directions and the magnetic fields and inductance induced by current variations are mutually canceled. The output cable 200 further includes an array of capacitors 240 for storing electrical charges. Each of the capacitors 240 has two electrodes 250 attached to the bottom plate 220 and electrode 245 attached to the top plate 210 through a via-connector 235 penetrating the insulation film 230. Each of these capacitors has a capacitance of about 450 μF. The capacitors 240 are employed to store electrical charges right on the output plate-cable 205 for rapid current ramp up during a startup stage. The electrical currents are not transmitted over an entire length of an output cable as that required in a conventional output cable of a power supply. The cable-plate 205 including the top and bottom plates are then soldered to a central process unit (CPU) connector 260 for connecting to the CPU. The power supply output cable 200 further includes a set of signal cable 270 for providing signals from the CPU to the power supply.

As that shown in FIG. 6A, the plate output cable 205 is further divided into a high and low voltage output plates separated by a insulation divider shown as dotted lines 280. A low voltage cable-plate 205-1 for providing a low voltage with six capacitors attached and a high voltage cable-plate with 19 capacitors attached for providing a high voltage are shown in FIG. 6A. The two divided cable-plates are formed as a single plate with insulation divider 280 and soldered to different sets of connector terminals for providing power to CPU.

According to FIGS. 6A to 6C and above descriptions, this invention discloses power supply cable for providing DC power from a power supply to an electronic device. The output cable includes a plate-cable includes two metal plates insulated with an insulation layer having multiple insulated plate-segments each of the plate-segment is provided for supplying power of a different voltage to the electronic device. In another preferred embodiment, the power supply cable further includes a plurality of capacitors disposed on the plate cable and electrically connected between the metal plates. In another preferred embodiment, the plurality of capacitors disposed on one a first plate of the two metal plates with a first electrical terminal for each of the capacitors connected to the first metal plate. The plate-cable further includes a plurality of via-connectors penetrating the insulation layer for connecting a second electrical terminal for each of the capacitors to a second plate of the two metal plates. In another preferred embodiment, the power supply cable further includes an electronic device connector socket soldering to an output end the plate-cable. In another preferred embodiment, the metal plates are cooper plates. In another preferred embodiment, the insulation layer for insulating the metal plates is a krypton layer. In another preferred embodiment, the plate-cable further includes several soldering holes each is provided for soldering to a connector for connecting to the power supply. In another preferred embodiment, the electronic device connector socket further includes a signal cable for providing signals from the electronic device to the power supply.

In a preferred embodiment, this invention discloses a power supply cable for providing DC power from a power supply to an electronic device. The power supply cable includes a plate-cable includes two metal plates insulated with an insulation layer. The power supply cable further includes a plurality of capacitors disposed on the plate cable and electrically connected between the metal plates.

This invention further discloses a method for configuring a power supply cable for providing DC power from a power supply to an electronic device. The method includes a step of forming a plate-cable by two metal plates and insulating the metal plates with an insulation layer and dividing the plate-cable into multiple insulated plate-segments for providing segment-specific voltage to the electronic device. In a preferred embodiment, this method further includes a step of disposing a plurality of capacitors on the plate cable and electrically connected between the metal plates. This invention further discloses a method of configuring a power supply cable for providing DC power from a power supply to an electronic device. The method includes a step of forming a plate-cable by two metal plates and insulating the metal plates with an insulation layer. The method further includes another step of disposing a plurality of capacitors on the plate cable and electrically connecting each of the capacitors between the metal plates.

The present invention therefore provides a novel configuration and method of design and manufacturing of an output cable for providing power to a microprocessor. The novel and improved output cable can significantly reduce the time required for ramping up the startup currents for operating an electronic device by configuring the output cable as plates and disposing capacitors on the output cable as capacitor array. The output plate cable further reduces the connector inductance during the time when there is a great rate of current variations such that the limitations and difficulties encountered in the prior art can be overcome. Specifically, the present invention provides a cable plate with capacitors attached to the plate for storing up electrical charges to rapidly providing current during a startup operation. The plate cable further is soldered to the electrical terminals connecting to the central process unit (CPU) to provide more reliable connection with lower resistance thus generating less voltage drops. The plate cable further has a current conduction configuration with the current generated magnetic field canceled out. By substantially canceling out the current generated-magnetic field, the inductance is reduced to a very low level. The voltage drop and heat production caused by connector inductance can be significantly reduced. Parallel conductive layers for conducting DC currents are implemented in the novel connector wherein the current generated magnetic fluxes are mutually canceled out. This novel configuration is employed on both the input end and the output end such that connector inductance can be substantially eliminated. The connector includes parallel conductive layers for conducting DC currents insulated by a heat conductive insulation layer. Furthermore, the connector is assembled and protected by a heat conductive insulation layer such that heat generated through current conducting in the connector can be more effectively removed.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

I claim:

1. A power supply cable for providing DC power from a power supply to a microprocessor of a personal computer comprising:
a plate-cable includes a first and a second metal plates insulated with an insulation layer between said first and second metal plates; and
a plurality of capacitors disposed on said plate cable wherein each of said capacitors having a first and second electrical terminals and each of said first and second electrical terminals connected to one of said first and second metal layers provided for storing electrical charges therein for transmitting through said metal layers for supplying power to said microprocessor.

2. The power supply cable of claim 1 wherein:
said plurality of capacitors disposed on said first metal plate with said first electrical terminal for each of said capacitors connected to said first metal plate; and
said plate-cable further includes a plurality of via-connectors penetrating said insulation layer for connecting said second electrical terminal for each of said capacitors to said second metal plate.

3. The power supply cable of claim 1 wherein:
said plate-cable further includes multiple insulated plate-segments each of said plate-segment is provided for supplying power of a different voltage to said microprocessor.

4. The power supply cable of claim 1 further comprising:
a microprocessor connector socket soldering to an output end said plate-cable.

5. The power supply cable of claim 1 wherein:
said first and second metal plates are cooper plates.

6. The power supply cable of claim 1 wherein:
said insulation layer for insulating said first and second metal plates is a krypton layer.

7. The power supply cable of claim 1 wherein:
said plate-cable further includes several soldering holes each is provided for soldering to a connector for connecting to said power supply.

8. The power supply cable of claim 4 wherein:
said microprocessor connector socket further includes a signal cable for providing signals from said microprocessor to said power supply.

9. A power supply cable for providing DC power from a power supply to an electronic device comprising:
a plate-cable includes two metal plates insulated with an insulation layer having multiple insulated plate-segments each of said plate-segment is provided for supplying power of a different voltage to said electronic device.

10. The power supply cable of claim 9 further comprising:
a plurality of capacitors disposed on said plate cable and electrically connected between said metal plates.

11. The power supply cable of claim 10 wherein:
said plurality of capacitors disposed on one a first plate of said two metal plates with a first electrical terminal for each of said capacitors connected to said first metal plate; and
said plate-cable further includes a plurality of via-connectors penetrating said insulation layer for connecting a second electrical terminal for each of said capacitors to a second plate of said two metal plates.

12. The power supply cable of claim 9 further comprising:
an electronic device connector socket soldering to an output end said plate-cable.

13. The power supply cable of claim 9 wherein:
said metal plates are cooper plates.

14. The power supply cable of claim 9 wherein:
said insulation layer for insulating said metal plates is a krypton layer.

15. The power supply cable of claim 9 wherein:
said plate-cable further includes several soldering holes each is provided for soldering to a connector for connecting to said power supply.

16. The power supply cable of claim 12 wherein:
said electronic device connector socket further includes a signal cable for providing signals from said electronic device to said power supply.

17. A power supply cable for providing DC power from a power supply to an electronic device comprising:
a plate-cable includes two metal plates insulated with an insulation layer; and
a plurality of capacitors disposed on said plate cable and electrically connected between said metal plates.

18. A method for configuring a power supply cable to provide DC power from a power supply to a microprocessor of a personal computer comprising:
forming a plate-cable by employing a first and a second metal plates insulated with an insulation layer between said first and second metal plates; and
disposing a plurality of capacitors on said plate cable and connecting a first electrical terminal for each of said capacitor to said first metal plate and connecting a second electrical terminal for each of said capacitor to said second metal plate for storing electrical charges therein for transmitting through said metal layers for supplying power to said microprocessor.

19. The method of claim 18 further comprising a step of:
forming a plurality of via-connectors penetrating said insulation layer for connecting said second electrical terminal for each of said capacitors to said second metal plate.

20. The method of claim 18 further comprising a step of:
dividing said plate-cable into multiple insulated plate-segments for supplying power of a segment-specific voltage to said microprocessor through each of said plate-segment.

21. The method claim 18 further comprising:
soldering a microprocessor connector socket to an output end said plate-cable.

22. The method claim 18 wherein:
said step of forming said plate-cable with said metal plates is a step of forming said plate-cable with cooper plates.

23. The method of claim 18 wherein:
said method of insulating said metal plates is a step of insulating said metal plates with a kapton layer.

24. The method of claim 18 further comprising a step of:
forming several soldering holes on said plate-cable for soldering to a connector for connecting to said power supply.

25. The method of claim 21 further comprising:
connecting a signal cable to said microprocessor connector socket for providing signals from said microprocessor to said power supply.

26. A method for configuring a power supply cable for providing DC power from a power supply to an electronic device comprising:
forming a plate-cable by two metal plates and insulating said metal plates with an insulation layer and dividing said plate-cable into multiple insulated plate-segments for providing segment-specific voltage to said electronic device.

27. The method of claim 26 further comprising:
disposing a plurality of capacitors on said plate cable and electrically connected between said metal plates.

28. A method of configuring a power supply cable for providing DC power from a power supply to an electronic device comprising:
forming a plate-cable by two metal plates and insulating said metal plates with an insulation layer;
disposing a plurality of capacitors on said plate cable and electrically connecting each of said capacitors between said metal plates.
